(19) United States
(12) Patent Application Publication
(10) Pub. No.: US 2004/0151258 A1
(43) Pub. Date: Aug. 5, 2004

(54) Bit likelihood calculation method and demodulation device

(76) Inventors: Yoshiko Saito, Kanagawa (JP); Mitsuru Uesugi, Kanagawa (JP)

Correspondence Address: Stevens Davis, Miller & Mosher, Suite 850, 1615 L Street NW, Washington, DC, 20036, US

(21) Appl. No.: 10/479,366

(22) PCT Filed: Mar. 10, 2003
(86) PCT No.: PCT/JP03/02769

(30) Foreign Application Priority Data
Mar. 12, 2002 (JP) 2002-67091

(51) Int. Cl. H03D 1/00

(52) U.S. Cl. 375/340

(57) ABSTRACT

The Viterbi calculation section 106 performs a Viterbi calculation by adding a branch metric to a path metric output from the metric selection section 105 and selecting a path having the smallest addition result and determines a surviving path having the smallest path metric and a second path having the second smallest path metric. The likelihood calculation section 107 compares each bit of the surviving path with the corresponding bit of the second path, sets lower likelihood for a bit having a different value than for a bit having the same value, and in this way calculates likelihood of each bit composing each symbol of the surviving path based on the relationship between the surviving path and the second path and further using mapping rules of the modulated signal. This makes it possible to calculate bit likelihood with a high degree of accuracy when demodulation is performed using Viterbi equalization to improve the error correcting capacity.

### TECHNICAL FIELD

The present invention relates to a bit likelihood calculation method and demodulation apparatus which calculates likelihood for each bit composing a symbol.

### BACKGROUND ART

One of conventional bit likelihood calculation methods in demodulating PSK-modulated signals is described in the Unexamined Japanese Patent Publication No. HEI 5-14213. In this method, a phase difference component and a distance error component from the origin are calculated from coordinate information in the demodulated phase space and bit likelihood is calculated using these components.

However, when Viterbi equalization such as MLSE is used to demodulate multi-value modulated signals, a symbol-based transmission signal string is output and signals are not output as bits which can be mapped in the phase space, which prevents bit likelihood from being calculated using the above described method.

### DISCLOSURE OF INVENTION

It is an object of the present invention to provide a bit likelihood calculation method and demodulation apparatus capable of calculating bit likelihood with a high degree of accuracy when demodulation is performed using Viterbi equalization to improve the error correcting capacity.

This object can be attained by calculating likelihood of each bit composing a symbol of a surviving path based on a relationship between the surviving path and a second path and using mapping rules of a modulated signal.

### BRIEF DESCRIPTION OF DRAWINGS

FIG. 1 is a block diagram showing a configuration of a demodulation apparatus according to an embodiment of the present invention;

FIG. 2 is a trellis diagram when Viterbi equalization is performed on a transmission signal string whose 1 symbol consists of 3 bits;

FIG. 3 is a trellis diagram to illustrate a third example; and

FIG. 4 is an 8PSK signal constellation.

### BEST MODE FOR CARRYING OUT THE INVENTION

With reference now to the attached drawings, an embodiment of the present invention will be explained below.

(Embodiment 1)

First, Viterbi equalization considering only one unit time (e.g., 1-symbol time) delay signal requiring binding conditions will be explained. In realizing Viterbi equalization, a pre-filter is often provided to prevent deterioration by timing jitter, etc. Here, when a pre-filter tap and a replica tap of Viterbi equalization are determined according to an MMSE (Minimum Mean Sequence Estimator) standard, all taps become “0”. To avoid this, a tap corresponding to a preceding signal of the replica tap is fixed at “1” as a binding condition. The present invention relates to a bit likelihood calculation method when such Viterbi equalization is used.

With reference to the attached drawings, an embodiment of the present invention will be explained in detail below.

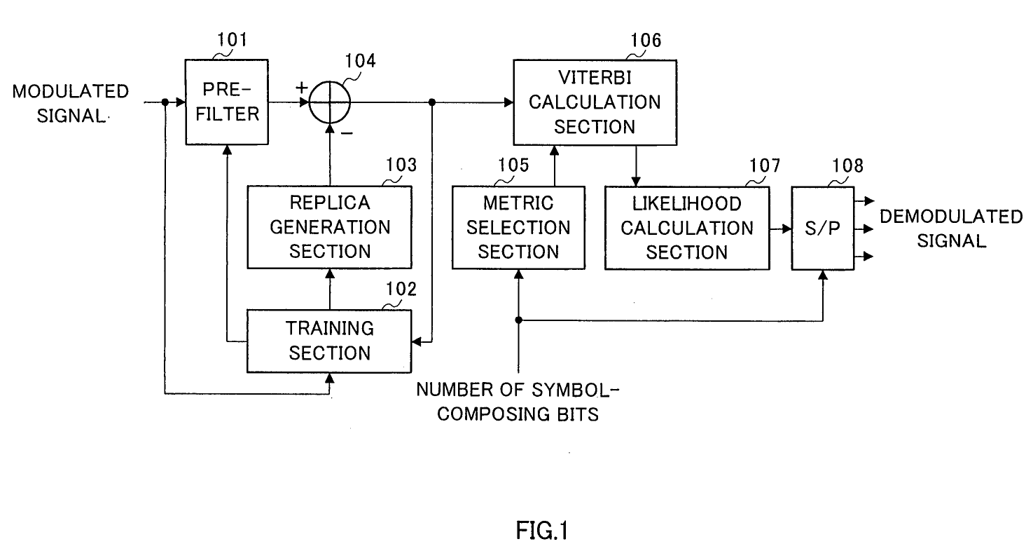

FIG. 1 is a block diagram showing a configuration of a demodulation apparatus according to an embodiment of the present invention.

A pre-filter 101 absorbs a synchronization shift such as timing jitter according to the range of the filter and the position of a principal signal. A training section 102 generates/updates a tap coefficient corresponding to the pre-filter 101 and replica generation section 103 using a modulated signal and a subtraction result from a subtraction section 104 which will be described later. The generated/updated tap coefficient is output to the pre-filter 101 and replica generation section 103.

The replica generation section 103 generates a replica signal based on the tap coefficient generated/updated by the training section 102 and outputs the replica signal to the subtraction section 104. The subtraction section 104 subtracts the replica signal generated by the replica generation section 103 from a received signal which has passed through the pre-filter 101 and outputs the subtraction result to the training section 102 and a Viterbi calculation section 106.

A metric selection section 105 decides the number of paths concentrated on 1 state based on the number of symbol-composing bits and outputs a path metric to the Viterbi calculation section 106 for each state.

The Viterbi calculation section 106 performs a Viterbi calculation by adding a branch metric to the path metric output from the metric selection section 105 and selecting a path corresponding to the minimum addition result, determines a surviving path having the smallest path metric and a second path having the second smallest path metric and outputs a symbol string of the surviving path and a symbol string of the second path to a likelihood calculation section 107.

The likelihood calculation section 107 calculates likelihood for each bit composing each symbol of the surviving path based on the relationship between the surviving path and second path and further using mapping rules of the modulated signal and outputs the symbol string of the surviving path and the calculated likelihood to an S/P conversion section 108.

The S/P conversion section 108 performs a serial/parallel conversion on the symbol string of the surviving path based on the number of symbol-composing bits and outputs the demodulated signal to a component (not shown) which carries out post-processing such as forward error correction.

Then, the bit likelihood calculation method by the likelihood calculation section 107 will be explained with specific examples.

(1) A first example is a method of comparing each bit of the surviving path with the corresponding bit of the second path and setting lower likelihood for a bit having a different value than for a bit having the same value.

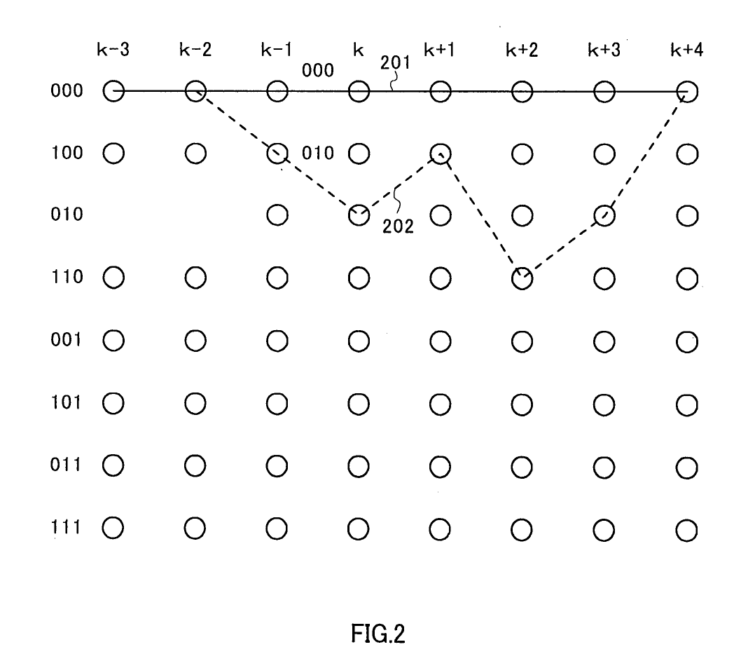

FIG. 2 is a trellis diagram when Viterbi equalization is performed on a transmission signal string whose 1 symbol consists of 3 bits. In FIG. 2, path 201 denotes a surviving path and path 202 denotes a second path. Furthermore, a symbol when time (N−1) transitions to time N is expressed by (3N, 3N+1, 3N+2) (N: natural number).

For example, when a transition from time (k−1) to time k in FIG. 2 takes place, the symbol of the surviving path is (0,0,0) and the symbol of the second path is (0,1,0) Therefore, when each bit of the surviving path is compared with the corresponding bit of the second path, only bit (3k+1) is different. Therefore, likelihood of this bit is set lower (e.g., 0.5 times) than other bits (3k and 3k+2).

(2) A second example is a method of calculating the number of bits whose value differs between the symbol of the surviving path and the corresponding symbol of the second path and setting lower likelihood for bits included in a symbol having more such bits.

For example, when Viterbi equalization is performed on a transmission signal string whose 1 symbol consists of 3 bits, suppose the symbol of a surviving path at time k is (0,0,0). Then, when the symbol of the second path at time k is also (0,0,0), the likelihood of three bits (3k, 3k+1, 3k+2) at time k are set to “1.0”. Furthermore, when the symbol of the second path at time k differs by 1 bit as, for example, (1,0,0), the likelihood of three bits (3k, 3k+1, 3k+2) at time k is set to “0.5”. Furthermore, when the symbol of the second path at time k differs by 2 bits as, for example, (1,1,0), the likelihood of three bits (3k, 3k+1, 3k+2) at time k is set to “0.3”. Furthermore, when the symbol of the second path at time k is (1,1,1) and all bits are different, the likelihood of three bits (3 k, 3k+1, 3k+2) at time k is set to “0.2”.

(3) A third example is a method of setting likelihood based on a difference between a branch metric of a surviving path and a branch metric which transitions to a state of the second path at the same time.

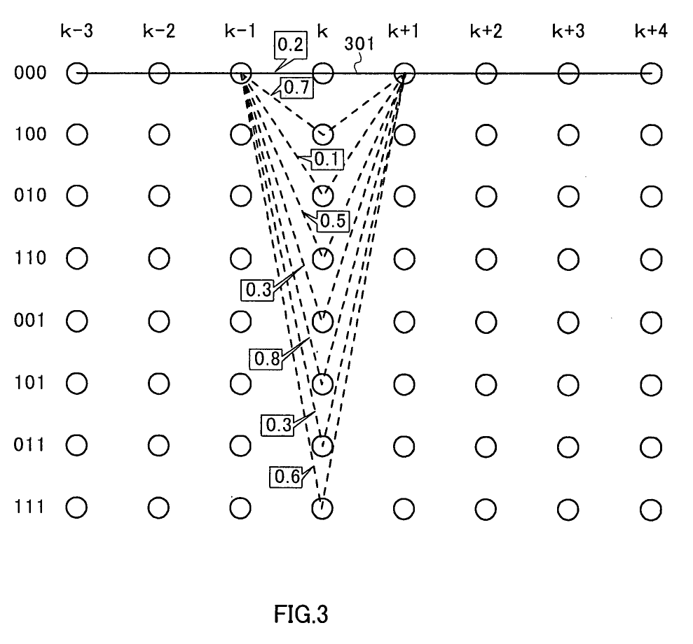

FIG. 3 is a trellis diagram to illustrate the third example. FIG. 3 shows a case where the respective states at times (k−1), k and (k+1) of a surviving path 301 are (0,0,0) and suppose the branch metric corresponding to transitions from a state (0,0,0) at time (k−1) to each state at time k is as follows:

Branch metric of transition (0,0,0) “0.2”

Branch metric of transition (1,0,0) “0.7”

Branch metric of transition (0,1,0) “0.1”

Branch metric of transition (1,1,0) “0.5”

Branch metric of transition (0,0,1) “0.3”

Branch metric of transition (1,0,1) “0.8”

Branch metric of transition (0,1,1) “0.3”

Branch metric of transition (1,1,1) “0.6”

In this case, a branch metric difference corresponding to a state (0,0,0) of the surviving path has the following values in the respective states of the transition destination:

Branch metric difference of transition (1,0,0) “0.5”

Branch metric difference of transition (0,1,0) “0.1”

Branch metric difference of transition (1,1,0) “0.3”

Branch metric difference of transition (0,0,1) “0.1”

Branch metric difference of transition (1,0,1) “0.6”

Branch metric difference of transition (0,1,1) “0.1”

Branch metric difference of transition (1,1,1) “0.4”

Then, for example, in the case of FIG. 3 above, the state of the second path at time k is (0,1,0), and therefore the likelihood of three bits (3k, 3k+1, 3k+2) at time k is set to “0.1”.

(4) A fourth example is a method of setting lower likelihood for a symbol at a shorter distance from a symbol which has been decided to be most likely in a mapping. This is because, the shorter the distance in a signal constellation, the higher the possibility that it may be wrong.

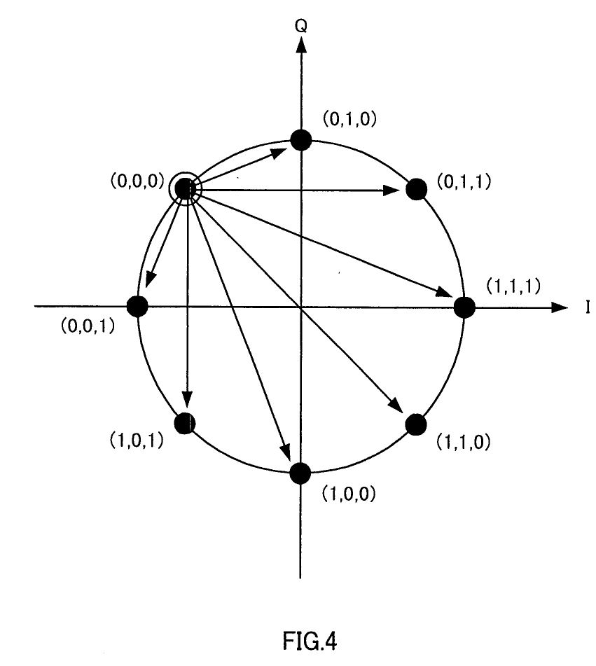

For example, in the 8PSK signal constellation in FIG. 4, when the symbol of a surviving path is (0,0,0), if symbols are grouped in order of likelihood of making a wrong decision, the symbol order is:

(0,0,1) and (0,1,0)>(1,0,1) and (0,1,1)>(1,0,0) and (1,1,1)>(1,1, 0)

In this case, lower likelihood is set for a symbol at a shorter distance from a decided symbol such as: likelihood of symbols (0,0,1) and (0,1,0) is set to “0.2”, likelihood of symbols (1,0,1) and (0,1,1) is set to “0.4”, likelihood of symbols (1,0,0) and (1,1,1) is set to “0.6” and likelihood of symbols (1,1,0) is set to “0.8”, and so on.

Then, for example, in the case of FIG. 2 above, since the state of the second path at time k is (0,1,0), likelihood of three bits (3k, 3k+1, 3k+2) at time k is set to “0.2”.

Thus, based on the relationship between the surviving path and the second path and using mapping rules of a modulated signal, it is possible to calculate likelihood of each bit composing a symbol of the surviving path.

Furthermore, it is also possible to calculate bit likelihood by combining the above described first example to fourth example as appropriate. In this case, it is further possible to calculate bit likelihood with a higher degree of accuracy and improve the error correcting capacity.

It is further possible to combine with other methods such as a method of setting higher likelihood for bits having higher error resistance in a mapping. This method of setting higher likelihood for bits having higher error resistance in a mapping is disclosed in detail in the Japanese Patent Application No. 2001-053189.

The above described embodiment has described the path having the second smallest path metric as the second path, but the present invention is not limited to this and also applicable to a case where any path other than the surviving path is regarded as the second path.

The above described embodiment also has described the case where a soft decision output value is calculated for equalization processing which is effective for compensating waveform distortion, but the present invention is not limited to this and is also applicable to error correction which is implemented with normal binary codes.

As is apparent from the above described explanations, the present invention can calculate likelihood of each bit composing a symbol of a surviving path and can thereby improve the error correcting capacity.

This application is based on the Japanese Patent Application No. 2002-067091 filed on Mar. 12, 2002, entire content of which is expressly incorporated by reference herein.

### INDUSTRIAL APPLICABILITY

The present invention is preferably applicable to a communication terminal apparatus and base station apparatus which perform equalization processing on the receiving side.

What is claimed is:

1. A bit likelihood calculation method comprising the steps of calculating a surviving path with the smallest path metric and a second path which is different from said surviving path through Viterbi equalization and calculating likelihood for each bit composing each symbol of said surviving path based on the relationship between said surviving path and said second path.

2. The bit likelihood calculation method according to claim 1, wherein each bit of the surviving path is compared with the corresponding bit of the second path and lower likelihood is set for bits having a different value than for bits having the same value.

3. The bit likelihood calculation method according to claim 1, wherein the number of bits whose value differs between a symbol of a surviving path and the corresponding symbol of the second path is calculated and lower likelihood is set for bits included in a symbol having more such bits

4. The bit likelihood calculation method according to claim 1, wherein likelihood is set based on a difference between a branch metric of a surviving path and a branch metric which transitions to a state of the second path at the same time.

5. The bit likelihood calculation method according to claim 1, wherein likelihood of each bit composing each symbol of the surviving path is calculated using mapping rules of a modulated signal.

6. The bit likelihood calculation method according to claim 5, where in lower likelihood is set for a bit included in a symbol at a shorter distance from a symbol which has been decided to be most likely in a mapping.

7. The bit likelihood calculation method according to claim 5, wherein higher likelihood is set for a bit having higher error resistance in a mapping.

8. A demodulation apparatus comprising:
a Viterbi calculation section that performs a Viterbi calculation to determine a surviving path having the smallest path metric and a second path which is different from said surviving path; and
a likelihood calculation section that calculates likelihood of each bit composing each symbol of said surviving path based on the relationship between said surviving path and said second path.

9. A communication terminal apparatus comprising:
a Viterbi calculation section that performs a Viterbi calculation to determine a surviving path having the smallest path metric and a second path which is different from said surviving path; and
a likelihood calculation section that calculates likelihood of each bit composing each symbol of said surviving path based on the relationship between said surviving path and said second path.

10. A base station apparatus comprising:
a Viterbi calculation section that performs a Viterbi calculation to determine a surviving path having the smallest path metric and a second path which is different from said surviving path; and
a likelihood calculation section that calculates likelihood of each bit composing each symbol of said surviving path based on the relationship between said surviving path and said second path.
